(19) United States
(12) Patent Application Publication
(10) Pub. No.: US 2023/0038009 A1
(43) Pub. Date: Feb. 9, 2023

(54) WAVELENGTH CONVERSION ELEMENT AND OPTICAL DEVICE

(71) Applicant: SHARP KABUSHIKI KAISHA, Sakai City, Osaka (JP)

(72) Inventors: SHIGERU AOMORI, Sakai City, Osaka (JP); HIDEOMI YUI, Sakai City, Osaka (JP); TORU KANNO, Sakai City, Osaka (JP); TOMOKO UEKI, Sakai City, Osaka (JP); MUTSUKO YAMAMOTO, Sakai City, Osaka (JP); HIROKAZU ICHINOSE, Sakai City, Osaka (JP)

(21) Appl. No.: 17/793,262

(22) PCT Filed: Jan. 25, 2021
(86) PCT No.: PCT/JP2021/002362

§ 371 Date: Jul. 15, 2022

(30) Foreign Application Priority Data
Mar. 18, 2020 (JP) 2020-047755

(51) Int. Cl. F21V 9/32

(52) U.S. Cl. CPC F21V 9/32; G03B 21/204

(57) ABSTRACT

A wavelength conversion element includes a plate, a wavelength conversion layer, and a macromolecular layer. The wavelength conversion layer has a facing surface facing the plate. The wavelength conversion layer contains an inorganic wavelength conversion material that emits light of a wavelength different from the wavelength of incident light. The macromolecular layer is disposed between the plate and the wavelength conversion layer. A part of the facing surface is in contact with the plate. At least a part of another portion of the facing surface is joined to the plate with the macromolecular aver interposed.

### TECHNICAL FIELD

The present invention relates to a wavelength conversion element and an optical device. This application claims priority to Japanese Patent Application No. 2020-4775, filed on Mar. 18, 2020, the content of which is herein incorporated by reference.

### BACKGROUND ART

Patent Literature 1 describes a base material, and a wavelength conversion member disposed on the base material and including a phosphor layer. The phosphor layer consists of phosphor particles and a light-transparency ceramic coupling the phosphor particles adjacent to each other. Patent Literature 1 describes inorganic binders, including silica and aluminum phosphate, as the light-transparency ceramic.

### CITATION LIST

### Patent Literature

Patent Literature 1: International Publication No, 2017/126441

### SUMMARY OF INVENTION

### Technical Problem

Wavelength conversion elements are required to prevent delamination of a wavelength conversion layer, such as a phosphor layer.

The main object of the present disclosure lies in providing a wavelength conversion element that is less likely to cause delamination of a wavelength conversion layer.

### Solution to Problem

A wavelength conversion element according to one aspect includes a plate, a wavelength conversion layer, and a macromolecular layer. The wavelength conversion layer has a facing surface facing the plate. The wavelength conversion layer contains an inorganic wavelength conversion material that emits light of a wavelength different from the wavelength of incident light. The macromolecular layer is disposed between the plate and the wavelength conversion layer. A part of the facing surface is in contact with the plate. At least a part of another portion of the facing surface is joined to the plate with the macromolecular layer interposed.

An optical device according to another aspect includes the wavelength conversion element according to the one aspect, and a light source that emits light to the wavelength conversion layer of the wavelength conversion element.

### BRIEF DESCRIPTION OF DRAWINGS

FIG. 1 is a schematic plan view of a wavelength conversion element according to a first embodiment.

FIG. 2 is a schematic sectional view taken along line II-II in FIG. 1.

FIG. 3 is a schematic plan view of a wavelength conversion element according to a second embodiment.

FIG. 4 is a schematic sectional view taken along line IV-IV in FIG. 3.

FIG. 5 is a schematic plan view of a wavelength conversion element according to a third embodiment.

FIG. 6 is a schematic sectional view taken along line VI-VI in FIG. 5.

FIG. 7 is a schematic plan view of a part of a wavelength conversion element according to a first modification.

FIG. 8 is a schematic plan view of a part of a wavelength conversion element according to a second modification.

FIG. 9 is a schematic sectional view of a wavelength conversion element according to a fourth embodiment.

FIG. 10 is a schematic diagram illustrating a configuration of an optical device according to a fifth embodiment.

FIG. 11 is a schematic plan view of a wavelength conversion element according to the fifth embodiment.

FIG. 12 is a schematic diagram illustrating a configuration of an optical device according to a sixth embodiment.

FIG. 13 is a schematic sectional view of a wavelength conversion element according to a third modification.

FIG. 14 is a schematic sectional view taken along line XIV-XIV in FIG. 13.

### DESCRIPTION OF EMBODIMENTS

The following describes example preferred embodiments of the present invention. However, the following embodiments are mere illustrative. The present invention is not limited to the following embodiments at all.

### First Embodiment

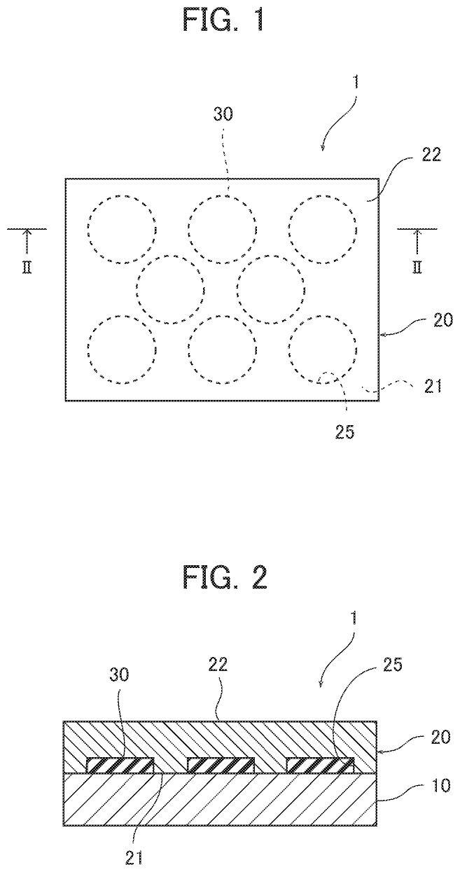

FIG. 1 is a schematic plan view of a wavelength conversion element 1 according to a first embodiment. FIG. 2 is a schematic sectional view taken along line II-II in FIG. 1.

As illustrated in FIG. 2, the wavelength conversion element 1 includes a plate 10, a wavelength conversion layer 20, and a macromolecular layer 30.

The plate 10 can be composed of, for instance, a metal plate, a ceramic plate, or other kinds of plate. The plate 10 preferably has high thermal conductivity so as to be able to dissipate the heat of the wavelength conversion layer 20 at high efficiency. From this view point, the plate 10 is preferably a metal plate and is more desirably, in particularly, an aluminum plate for instance. Alternatively, the plate 10 may be composed of, for instance, a metal plate, such as an aluminum plate, and a coating layer covering the surface of the metal plate.

The shape and size of the plate 10 are not limited particularly. The plate 10 may have, for instance, a circular shape, a circular plate shape, a polygonal shape, an elliptic shape, an oval shape, or other shapes. The plate 10 can have, but not limited to, a thickness of 0.5 to 2.0 mm inclusive for instance.

The wavelength conversion layer 20 is disposed on the plate 10. The wavelength conversion layer 20 is a layer that emits, upon receiving light (excitation light) of a particular wavelength, light of a wavelength different from that of the excitation light, typically light of a longer wavelength than the excitation light.

The wavelength conversion layer 20 contains an inorganic wavelength conversion material. The inorganic wavelength conversion material emits, upon receiving light (excitation light) of a particular wavelength, light of a wavelength different from that of the excitation light, typically light of a longer wavelength than the excitation light. In this embodiment, the inorganic wavelength conversion material includes an inorganic wavelength conversion material, such as an inorganic phosphor for instance.

Specific examples of the inorganic wavelength conversion material include YAG:Ce(Y₃Al₅O₁₂:Ce³⁺), CaAlSiN₃:Eu²⁺, Ca-α-SiAlON:Eu²⁺, β-SiAlON:Eu²⁺, Lu₃Al₅O₁₂:Ce³⁺(LuAG:Ce), (Sr,Ca,Ba,Mg)₁₀(PO₄)₆C₁₂Eu, BaMgAl₁₀O₁₇:Eu²⁺, and (Sr,Ba)₃MgSi₂O₈:Eu²⁺.

A plurality of inorganic wavelength conversion materials may include, for instance, one kind of inorganic wavelength conversion materials or a plurality of kinds of inorganic wavelength conversion materials.

The shape of the inorganic wavelength conversion material is not limited particularly. The inorganic wavelength conversion material may have, for instance, a particulate shape, a spherical shape, an elliptic spherical shape, a needle shape, a polygonal column shape, a cylindrical column shape, or other shapes.

The particle diameter of the plurality of inorganic wavelength conversion materials is not limited particularly. The plurality of inorganic wavelength conversion materials preferably have, for instance, an average particle diameter of 1 to 50 μm inclusive and more desirably have an average particle diameter of 5 to 30 μm inclusive.

Further, a plurality of inorganic wavelength conversion materials of different average particle diameters may be combined.

The wavelength conversion layer 20 may be composed of only a plurality of inorganic wavelength conversion materials, but preferably further contains a binder in addition to the plurality of inorganic wavelength conversion materials. The wavelength conversion layer 20 further preferably contains an inorganic binder made of an inorganic material. Specific examples of a preferably used inorganic binder include alumina, silica, silicon nitride, aluminum nitride, zinc oxide, and tin oxide.

The inorganic binder within the wavelength conversion layer 20 preferably has a content of 10 to 40 vol % inclusive for instance.

The wavelength conversion layer 20 preferably contains only an inorganic material substantially. That is, the wavelength conversion layer 20 is preferably an inorganic wavelength conversion layer.

As illustrated in FIG. 2, the wavelength conversion layer 20 has a facing surface 21 facing the plate 10, and a main surface 22 opposite to the plate 10. At least one recess 25 is formed in the facing surface 21. Thus, at least a part of a portion of the facing surface 21 provided with no recess 25 is in contact with the plate 10, and a portion of the facing surface 21 provided with the recess 25 is not in contact with the plate 10. That is, a part of the facing surface is in contact with the plate 10.

The macromolecular layer 30 is disposed between the plate 10 and the wavelength conversion layer 20. In detail, the macromolecular layer 30 is disposed in the recess 25, provided in the facing surface 21 of the wavelength conversion layer 20. Although preferably provided in the entire recess 25, the macromolecular layer 30 may be provided a part of the recess 25. That is, the recess 25 may have a portion where the macromolecular layer 30 is not located.

To be specific, in this embodiment, as illustrated in FIG. 1, a plurality of macromolecular layers 30 are disposed between the plate 10 and the wavelength conversion layer 20. The macromolecular layer 30 is disposed in each of the plurality of recesses 25. The plurality of macromolecular layers 30 are spaced from each other in matrix in an x-direction in FIG. 1 and in a y-direction oblique (typically, orthogonal) to the x-direction.

The shape of each of the plurality of macromolecular layers 30 is not particularly limited as long as the macromolecular layers 30 are provided between the plate 10 and the wavelength conversion layer 20. The macromolecular layers 30 may have, for instance, a circular shape, an elliptic shape, or a rectangular shape in a plan view.

The macromolecular layer 30 contains macromolecules. The macromolecular layer 30 is preferably composed of, for instance, resin or a resin composition.

The macromolecular layer 30 preferably contains macromolecules having high thermal durability. The macromolecular layer 30 preferably contains, for instance, at least one of silicone, polyimide, polyurethane, epoxy resin, and phenolic resin. The macromolecular layer 30 may be composed of, for instance, a resin composition containing at least one of silicone, polyimide, polyurethane, epoxy resin, and phenolic resin and containing a filler. Specific examples of a preferably used filler include silica and alumina.

As illustrated in FIG. 2, the macromolecular layer 30 is in contact with both the portion of the facing surface 21 provided with the recess 25 and the plate 10, In this embodiment, the macromolecular layer 30 is specifically joined to both the portion of the facing surface 21 provided with the recess 25 and the plate 10. Thus, at least a part of a portion of the facing surface 21 excluding a portion being in contact with the plate 10 is joined to the plate 10 with the macromolecular layer 30 interposed therebetween. To be specific, at least a part of the portion of the facing surface 21 provided with the recess 25 is joined to the plate 10 with the macromolecular layer 30 interposed therebetween.

By the way, the temperature of a wavelength conversion layer rises upon receiving excitation light. The thermal expansion coefficient of a plate and the thermal expansion coefficient of a wavelength conversion layer are normally different from each other. For instance, the thermal expansion coefficient of a plate is larger than the thermal expansion coefficient of a wavelength conversion layer when the plate is a metal plate, and when the wavelength conversion layer contains an inorganic wavelength conversion material. Hence, the amount of thermal expansion of the wavelength conversion layer and the amount of thermal expansion of the plate are different from each other when the temperatures of the wavelength conversion layer and plate have risen. This difference in thermal expansion amount between the wavelength conversion layer and the plate possibly causes the wavelength conversion layer to delaminate from the plate.

In the wavelength conversion element 1 according to this embodiment, a part of the facing surface 21 of the wavelength conversion layer 20 is in contact with the plate 10, and at least a part of another portion of the facing surface 21 is joined to the plate 10 with the macromolecular layer 30 interposed therebetween. Hence, the wavelength conversion layer 20 is less likely to delamination from the plate 10.

In detail, a part of the facing surface of the wavelength conversion layer 20 is in contact with the plate 10. The wavelength conversion layer 20, which contains an inorganic wavelength conversion material and the foregoing inorganic binder, has high thermal conductivity. Hence, the heat of the wavelength conversion layer 20 easily transmits to the plate 10 even when the wavelength conversion layer 20 radiates heat upon receiving excitation light. Thus, a temperature rise in the wavelength conversion layer 20 can be prevented. Hence, the thermal expansion difference between the wavelength conversion layer 20 and the plate 10 can be reduced. Thus, the delamination of the wavelength conversion layer 20 from the plate 10 can be prevented.

Furthermore, in the wavelength conversion element 1 according to this embodiment, at least a part of the facing surface 21 is in joined to the plate 10 with the macromolecular layer 30 interposed therebetween. The macromolecular layer 30 can function as a buffer layer that mitigates a stress that is caused by the thermal expansion difference between the wavelength conversion layer 20 and the plate 10. Additionally, the macromolecular layer 30, which contains macromolecules, has a higher strength of adhesion to the plate 10 than the wavelength conversion layer 20, containing an inorganic wavelength conversion material. Thus, the delamination of the wavelength conversion layer 20 from the plate 10 can be further prevented.

As such, the wavelength conversion layer 20 is in direct contact with the plate 10 and is joined to the plate 10 by the macromolecular layer 30, thus successfully preventing a temperature rise in the wavelength conversion layer 20. Furthermore, the macromolecular layer 30 can reduce a stress that is caused by the thermal expansion difference and can enhance the strength of adhesion between the wavelength conversion layer 20 and the plate 10. Accordingly, the delamination of the wavelength conversion layer 20 from the plate 10 can be prevented efficiently.

The wavelength conversion element 1 has a plurality of macromolecular layers 30. This enables a plurality of portions being in direct contact with the plate 10, and a plurality of portions joined by the macromolecular layers 30 to be disposed on the facing surface 21 dispersedly. Thus, a local temperature rise in the wavelength conversion layer 20 can be prevented. Further, the strength of adhesion of the wavelength conversion layer 20 to the plate 10 can be enhanced overall. Furthermore, a stress that occurs between the wavelength conversion layer 20 and the plate 10 can be mitigated overall. Accordingly, the delamination of the wavelength conversion layer 20 from the plate 10 can be prevented more efficiently.

In the wavelength conversion element 1, the area ratio of a region where the facing surface 21 and the macromolecular layers 30 are in contact together, to the area of the facing surface 21 in a plan view is preferably 10 to 70% inclusive and is more desirably 20 to 60% inclusive in order to achieve both high thermal conductivity between the wavelength conversion 1.5 layer 20 and the plate 10, and delamination prevention through provision of the macromolecular layers 30.

To further increase the buffer effect of the macromolecular layer 30, the macromolecular layer 30 preferably has an elasticity coefficient lower than the elasticity coefficient of the wavelength conversion layer 20. To be specific, E_{W}/E_{P}, the ratio between the elasticity coefficient, Eₚ, of the macromolecular layer 30 and the elasticity coefficient, E_{W}, of the wavelength conversion layer 20, is preferably hundred-thousand-fold or greater and is more desirably million-fold or greater.

From a similar view point, the macromolecular layer 30 preferably has a linear thermal expansion coefficient higher than the linear thermal expansion coefficient of the wavelength conversion layer 20. To be specific, the linear thermal expansion coefficient of the macromolecular layer 30 is higher than the linear thermal expansion coefficient of the wavelength conversion layer 20 by 10 times or greater and is more desirably higher by 100 times or greater.

To further increase the thermal conduction from the wavelength conversion layer 20 to the plate 10, the wavelength conversion layer 20 preferably contains an inorganic binder.

### Second Embodiment

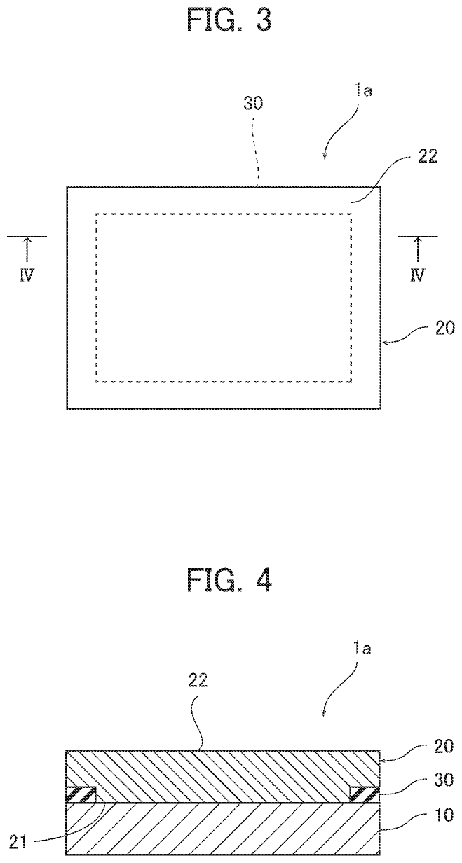

FIG. 3 is a schematic plan view of a wavelength conversion element 1a according to a second embodiment. FIG. 4 is a schematic sectional view taken along line IV-IV in FIG. 3.

The first embodiment has described an instance where the plurality of macromolecular layers 30 are provided in matrix. However, the present invention is not limited to this configuration.

In the wavelength conversion element 1a according to this embodiment, the macromolecular layer 30 is provided on the edge of the wavelength conversion layer 20. The macromolecular layer 30 is formed into a frame shape. The macromolecular layer 30 is disposed between the edge of the wavelength conversion layer 20 and the plate 10.

Even in an instance like that in this embodiment, where the macromolecular layer 30 is provided on the edge of the wavelength conversion layer 20, the delamination of the wavelength conversion layer 20 can be prevented, like the first embodiment. Further, in an instance where the middle of the wavelength conversion layer 20 undergoes excitation light irradiation, for instance, the temperature of the middle of the wavelength conversion layer 20 easily rises, and the temperature at the edge of the same is less likely to rise. Hence, the wavelength conversion layer 20 has a stress caused by a temperature difference, but the macromolecular layer 30 provided on the edge mitigates the stress, and thus, a reduction in the adhesion strength of the macromolecular layer 30 can be prevented efficiently. Further, the temperature of the macromolecular layer 30 on the edge is also less likely to rise, and thus, the adhesion strength of the macromolecular layer 30 is less likely to reduce. Accordingly, the delamination of the wavelength conversion layer 20 can be prevented efficiently. To efficiently prevent the delamination of the wavelength conversion layer 20, the macromolecular layer 30 is preferably provided annularly in entirety.

### Third Embodiment

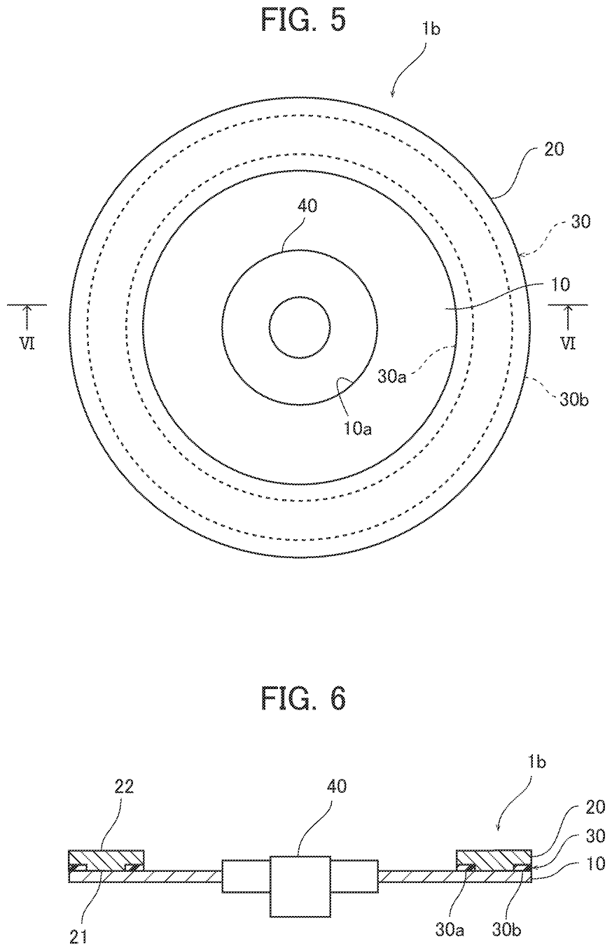

FIG. 5 is a schematic plan view of a wavelength conversion element 1b according to a third embodiment. FIG. 6 is a schematic sectional view taken along line VI-VI in FIG. 5.

The first and second embodiments have described an instance where the wavelength conversion elements 1 and 1a have a rectangular shape. However, the present invention is not limited to this configuration. The wavelength conversion elements may have, for instance, a circular plate shape or other shapes. This embodiment describes the wavelength conversion element 1b constituting a fluorescent wheel of a circular plate shape.

The plate 10 has a circular plate shape in the wavelength conversion element 1b. As illustrated in FIG. 6, the plate 10 has a through-hole 10a formed in its middle. A shaft 40 is inserted into the through-hole 10a. The plate 10 rotates along with rotations of the shaft 40 inserted in the through-hole 10a.

The wavelength conversion layer 20 is provided on the perimeter of the plate 10. The wavelength conversion layer 20 is formed into a ring shape (annular shape). In this embodiment, the whole of the wavelength conversion layer 20 contains the same wavelength conversion material and emits light of the same wavelength. However, the present invention is not limited to this configuration. The wavelength conversion layer may be, for instance, disposed in the circumferential direction and include a plurality of wavelength conversion layers that emit light of wavelengths different from each other. To be specific, the wavelength conversion layer may be disposed in the circumferential direction and include a wavelength conversion layer that emits red light, a wavelength conversion layer that emits green light, and a wavelength conversion layer that emits blue light.

As illustrated in FIG. 5, in this embodiment, the macromolecular layer 30 is provided at each of both ends (inner end and outer end) of the wavelength conversion layer 20. To be specific, the wavelength conversion element 1b has an inner macromolecular layer 30a and an outer macromolecular layer 30b as the macromolecular layer 30. The inner macromolecular layer 30a is disposed between the inner perimeter of the wavelength conversion layer 20 formed into a ring shape and the plate 10. In contrast, the outer macromolecular layer 30b is disposed between the outer perimeter of the wavelength conversion layer 20 formed into a ring shape and the plate 10.

The macromolecular layer 30 is provided in this embodiment as well, like that in the foregoing embodiment. Hence, the delamination of the wavelength conversion layer 20 can be prevented.

Further, in this embodiment, the joining strength of each of both ends in the radius direction of the wavelength conversion layer 20 is improved by the inner macromolecular layer 30a and the outer macromolecular layer 30b, and hence, the delamination of the wavelength conversion layer 20 can be prevented more efficiently.

Furthermore, in the wavelength conversion element 1b, constituting a fluorescent wheel, the middle in the radius direction of the wavelength conversion layer 20 is normally irradiated with excitation light to thus tend to have a high temperature. Hence, the temperatures of the inner macromolecular layer 30a and outer macromolecular layer 30b are less likely to rise. Accordingly, the joining strength of the inner macromolecular layer 30a and outer macromolecular layer 30b is less likely to reduce, and the delamination of the wavelength conversion layer 20 can be prevented more efficiently.

First Modification and Second Modification

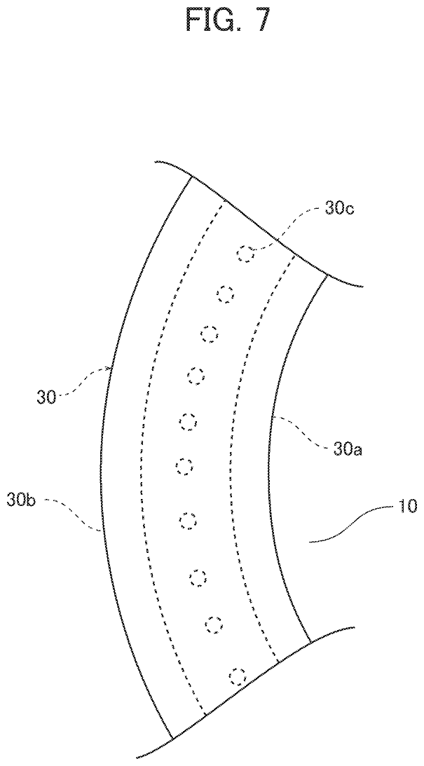

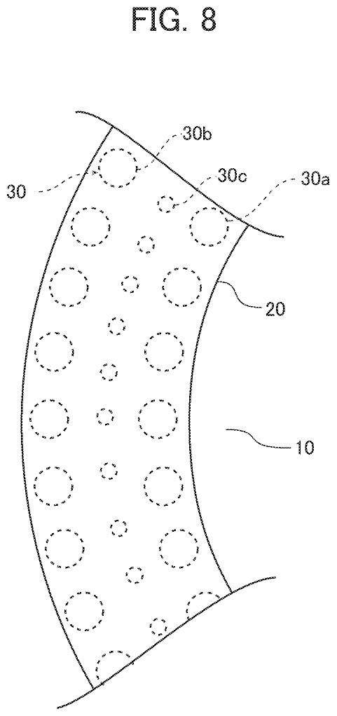

FIG. 7 is a schematic plan view of a part of a wavelength conversion element according to a first modification. FIG. 8 is a schematic plan view of a part of a wavelength conversion element according to a second modification.

The third embodiment has described an instance where the macromolecular layer 30 is composed of the inner macromolecular layer 30a and the outer macromolecular layer 30b. However, the present invention is not limited to this configuration. For instance, as illustrated in FIG. 7, in the first modification, the macromolecular layer 30 includes a plurality of middle macromolecular layers 30c in addition to the inner macromolecular layer 30a and the outer macromolecular layer 30b. The plurality of middle macromolecular layers 30c are disposed between the middle in the radius direction of the wavelength conversion layer 20 and the plate 10. The plurality of middle macromolecular layers 30c are spaced from each other in the circumferential direction. The shape of the plurality of middle macromolecular layers 30c in a plan view is not limited particularly, but is circular for instance.

Providing the middle macromolecular layers 30c, like those in the first modification, can efficiently prevent the middle in the radius direction of the wavelength conversion layer 20, which is susceptible to a temperature rise resulting from excitation light irradiation, from delaminating from the plate 10.

To efficiently prevent the delamination of the wavelength conversion layer 20, the rates of existence of the inner macromolecular layer 30a and outer macromolecular layer 30b in their individual circumferential directions are preferably higher than the rate of existence of the middle macromolecular layers 30c in their circumferential direction. The sizes of the inner macromolecular layer 30a and outer macromolecular layer 30b in their individual radius directions are preferably larger than the size of the middle macromolecular layers 30 in their radius direction.

It is noted that the first modification has described an instance where each of the inner macromolecular layer 30a and the outer macromolecular layer 30b has an annular shape. However, the present invention is not limited to this configuration. For instance, as illustrated in FIG. 8, each of the inner macromolecular layer 30a and the outer macromolecular layer 30b may be composed of a plurality of macromolecular layers spaced from each other in the circumferential direction. That is, for instance, at least one of the inner macromolecular layer 30a, the outer macromolecular layer 30b, and the middle macromolecular layer 30c may be provided in the form of dots.

### Fourth Embodiment

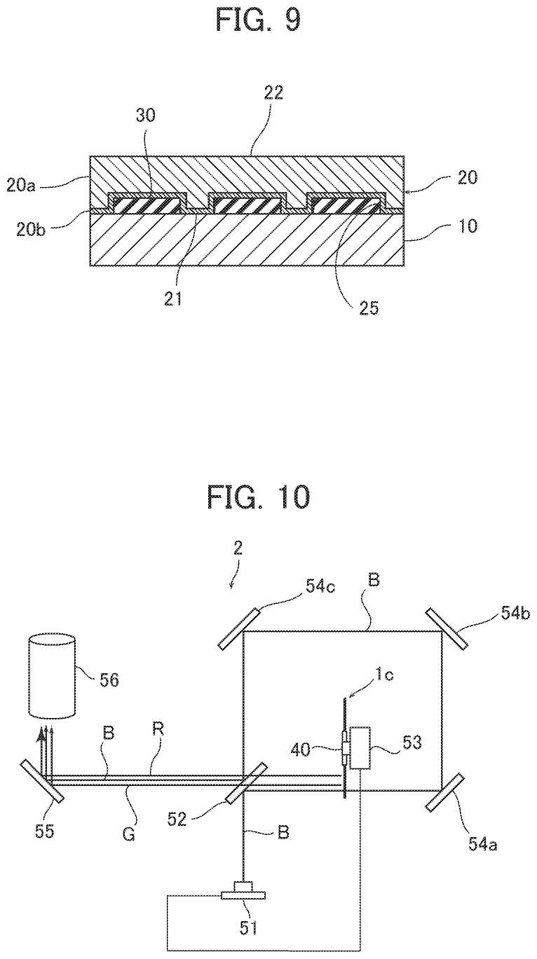

FIG. 9 is a schematic sectional view of a wavelength conversion element according to a fourth embodiment.

The first to third embodiments have described an instance where the whole of the wavelength conversion layer 20 contains a wavelength conversion material. However, the present invention is not limited to this configuration. The wavelength conversion layer 20 may have, for instance, a wavelength-conversion-member-containing portion containing a wavelength conversion member, and a wavelength-conversion-member-free portion containing no wavelength conversion member.

As illustrated in FIG. 9, in this embodiment, the wavelength conversion layer 20 has a wavelength-conversion-material-containing layer 20a and a diffusion layer 20b. The wavelength-conversion-material-containing layer 20a is a layer including a wavelength conversion material and an inorganic binder. In contrast, the diffusion layer 20b contains no wavelength conversion material. In this embodiment, the diffusion layer 20b is composed of an inorganic binder and an optical-diffusion material. The diffusion layer 20b is disposed between the wavelength-conversion-material-containing layer 20a and the plate 10. The optical-diffusion material is preferably a material having a refractive index different greatly from that of the inorganic binder and can be composed of a particulate material consisting of, for instance, titanium oxide, zirconia oxide, zinc oxide, silica, and other things, or an air layer like a void contained in the inorganic binder. The average particle diameter of these particles is, for instance, several hundred nanometers to several micrometers.

Even in an instance where the wavelength conversion layer 20 includes the diffusion layer 20b, like that in this embodiment, the macromolecular layer 30 is provided, thus offering an effect substantially similar to that in the first to third embodiments.

### Fifth Embodiment

FIG. 10 is a schematic diagram illustrating a configuration of an optical device according to a fifth embodiment.

The wavelength conversion elements according to the present invention can be used in various optical devices. This embodiment describes, as a kind of optical device, a projector including a wavelength conversion element according to one embodiment.

An optical device 2 illustrated in FIG. 10 constitutes a projector. The optical device 2 has a light source 51. The light source 51 can be composed of, for instance, a light emitting diode (LED) or a laser element. This embodiment describes an instance where the light source 51 is composed of a laser diode (LD that emits blue light B.

A dichroic mirror 52 that selectively reflects the wavelength of the blue light B is disposed on the optical-output side of the light source 51. The blue light B emitted from the light source 51 is reflected by the dichroic mirror 52. The reflected blue light B enters a wavelength conversion element 1c.

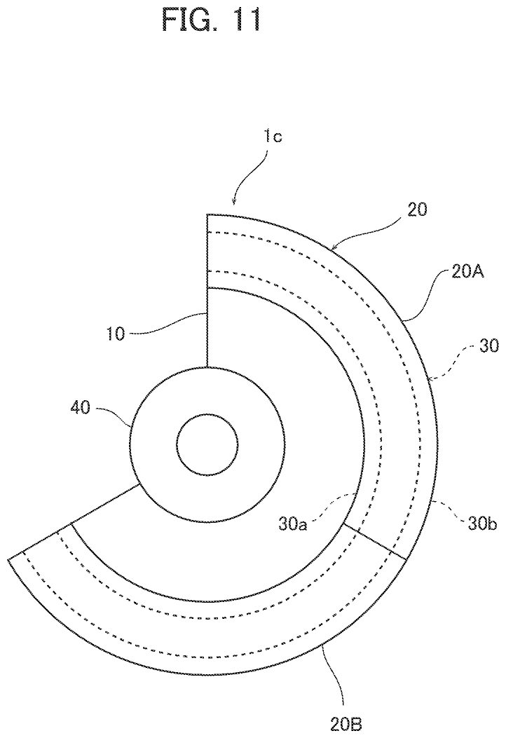

FIG. 11 is a schematic plan view of the wavelength conversion element c in the fifth embodiment.

The wavelength conversion element 1c constitutes a fluorescent wheel. As illustrated in FIG. 11, in the wavelength conversion element 1c, the plate 10 has a circular plate shape partly cut in the circumferential direction. In this embodiment, the plate 10 is composed of a metal plate and reflects light.

The plate 10 is fastened to the shaft 40 connected to a rotation device 53 illustrated in FIG. 10. The rotation device 53 causes the plate 10 to rotate along with rotations of the shaft 40.

The wavelength conversion layer 20 having a fan shape with its inner portion in the radius direction cut is formed on the plate 10. The macromolecular layer 30 including the inner macromolecular layer 30a and the outer macromolecular layer 30b is disposed between the wavelength conversion layer 20 and the plate 10. Hence, the delamination of the wavelength conversion layer 20 from the plate 10 is prevented in this embodiment as well.

The wavelength conversion layer 20 includes a green-wavelength conversion layer 20A and a red-wavelength conversion layer 20B disposed in the circumferential direction. The green-1.5 wavelength conversion layer 20A emits green light G upon receiving the blue light B from the light source 51. The red-wavelength conversion layer 20B emits red light R upon receiving the blue light B from the light source 51. The light from the green-wavelength conversion layer 20A and red wavelength conversion layer 20B is reflected by the plate 10.

Upon the rotation device 53 being driven, thus rotating the plate 10, the blue light B from the light source 51 enters a region provided with no wavelength conversion element 1, a region provided with the green-wavelength conversion layer 20A, and a region provided with the red-wavelength conversion layer 20B in this order repeatedly.

The blue light B entered the region provided with no wavelength conversion element 1 travels straight as it is and is guided to the dichroic mirror 52 by optical elements 54a, 54b, and 54c illustrated in FIG. 10. The blue light B is reflected toward an optical element 55 by the dichroic mirror 52.

The green light G exits from the green-wavelength conversion layer 20A upon entrance of the blue light B into the region provided with the green-wavelength conversion layer 20A. The green light G passes through the dichroic mirror 52 and then enters the optical element 55.

The red light R exits from the red-wavelength conversion layer 20B upon entrance of the blue light B into the region provided with the red-wavelength conversion layer 20B. The red light R passes through the dichroic mirror 52 and then enters the optical element 55.

The blue light B, the green light G, and the red light R is then individually reflected toward a projection optical system 56 by the optical element 55 and is projected by the projection optical system 56.

### Sixth Embodiment

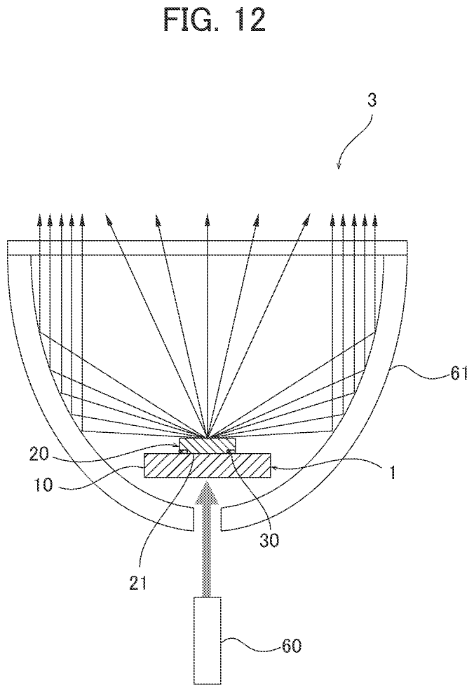

FIG. 12 is a schematic diagram illustrating a configuration of an optical device according to a sixth embodiment.

This embodiment describes an optical device 3, which is a light source device, illustrated in FIG. 12 as an example optical device including a wavelength conversion element. It is noted that the optical device 3 is suitably used for, for instance, a transmissive laser headlight (vehicle headlight) and other kinds of lights.

The optical device 3 includes the wavelength conversion element 1 and a light source 60. The light source 60 emits excitation light of the wavelength conversion layer 20 to the wavelength conversion layer 20 of the wavelength conversion element 1. In this embodiment, the plate 10 allows light from the light source 60 to pass. Hence, the light from the light source 60 enters the wavelength conversion layer 20. Light (e.g., fluorescence) emitted from the wavelength conversion layer 20 is reflected by a reflector 61 and exits as collimated light.

The macromolecular layer 30 is provided in this embodiment as well, and hence, the delamination of the wavelength conversion layer 20 from the plate 10 can be prevented efficiently.

Third Modification

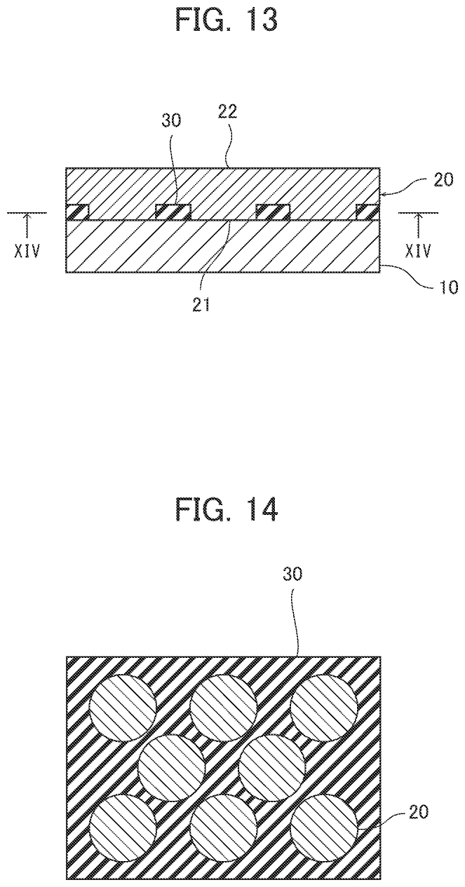

FIG. 13 is a schematic sectional view of a wavelength conversion element according to a third modification. FIG. 14 is a schematic sectional view taken along line XIV-XIV in FIG. 13.

The first embodiment has described an instance where the macromolecular layer 30 is provided in the form of islands. However, the present invention is not limited to this configuration. The macromolecular layer 30 is not particularly limited as long as it is provided in a part between the wavelength conversion layer 20 and the plate 10. To be specific, for instance, the macromolecular layer 30 may have a plate shape having a plurality of through-holes, like the wavelength conversion element illustrated in FIG. 13 and FIG. 14.

It is noted that the fact that the shape of the macromolecular layer 30 is not limited holds true for the fourth embodiment.

1. A wavelength conversion element comprising:
a plate;
a wavelength conversion layer having a facing surface facing the plate, the wavelength conversion layer containing an inorganic wavelength conversion material that emits light of a wavelength different from a wavelength of incident light; and
a macromolecular layer disposed between the plate and the wavelength conversion layer,
wherein a part of the facing surface is in contact with the plate, and at least a part of another portion of the facing surface is joined to the plate with the macromolecular layer interposed.

2. The wavelength conversion element according to claim 1, wherein the macromolecular layer has an elasticity coefficient lower than an elasticity coefficient of the wavelength conversion layer.

3. The wavelength conversion element according to claim 1, wherein the macromolecular layer has a linear thermal expansion coefficient higher than a linear thermal expansion coefficient of the wavelength conversion layer.

4. The wavelength conversion element according to claim 1, wherein the wavelength conversion layer contains an inorganic binder.

5. The wavelength conversion element according to claim 1, wherein a plurality of the macromolecular layers are provided.

6. The wavelength conversion element according to claim 5, wherein the plurality of macromolecular layers include a macromolecular layer disposed between each of both ends of the wavelength conversion layer in one direction and the plate.

7. The wavelength conversion element according to claim 5, wherein the plurality of macromolecular layers include a plurality of macromolecular layers disposed in matrix.

8. The wavelength conversion element according to claim 1, wherein the macromolecular layer contains at least one of silicone, polyimide, polyurethane, epoxy resin, and phenolic resin.

9. The wavelength conversion element according to claim 1, wherein the macromolecular layer contains an inorganic material.

10. The wavelength conversion element according to claim 1, wherein an area ratio of a region where the facing surface and the macromolecular layer are in contact together, to an area of the facing surface in a plan view is 20 to 60% inclusive.

11. The wavelength conversion element according to claim 1, wherein the plate is a metal plate.

12. An optical device comprising:
the wavelength conversion element according to claim 1; and
a light source that emits light to the wavelength conversion layer of the wavelength conversion element.

13. The optical device according to claim 12, wherein the macromolecular layer is provided in a region that is not irradiated with light from the light source.

14. The optical device according to claim 12, wherein the macromolecular layer is provided in a region including a region that is irradiated with light from the light source.
